(19) United States
(12) Patent Application Publication
(10) Pub. No.: US 2009/0054004 A1
(43) Pub. Date: Feb. 26, 2009

(54) Biasing for Stacked Circuit Configurations

(75) Inventors: Yuen Hui Chee, Sunnyvale, CA (US); Thomas H. Lee, Burlingame, CA (US)

Correspondence Address: THE MUELLER LAW OFFICE, P.C., 12951 Harwick Lane, San Diego, CA, 92130, US

(73) Assignee: ZeroG Wireless, Inc., Delaware Corporation, Sunnyvale, CA (US)

(21) Appl. No.: 11/841,825

(22) Filed: Aug. 20, 2007

(51) Int. Cl. H04B 1/38; H03F 3/04

(52) U.S. Cl. 455/73; 330/296

(57) ABSTRACT

A biasing scheme for compensating for a difference in biasing currents between a first circuit element (10) and second circuit element (32) in a stacked circuit configuration. A current-difference source (38) generates a difference current that is substantially equal to the difference between the biasing currents of the first circuit element (10) and second circuit element (32) in order to compensate for process, temperature and supply variations.

### FIELD OF THE INVENTION

The present invention relates to stacked circuit configurations, and more specifically to methods and apparatuses for biasing stacked circuit configurations.

### BACKGROUND OF THE INVENTION

In response to demands for reduction in the size and current consumption of electronic equipment, there has been an increased demand for circuit configurations that have multiple circuit functions but share the same DC current. Such configurations are sometimes referred to as stacked circuits. Although the term “stacked circuit” may be used to refer specifically to circuits with vertical arrangements, the term is used herein to refer more generally to any circuit with multiple circuit functions that share the same DC current. One example of a stacked circuit is a stacked/LNA mixer. A stacked/LNA mixer is a combination of a low noise amplifier (LNA) and mixer. Stacked LNA/mixers and other stacked combinations are commonly used in communications circuits such as transceivers.

Separate circuit elements, such as a separate LNA or a separate mixer, require appropriate biasing in order to achieve desired performance parameters. Biasing generally takes the form of providing a fixed biasing current or a fixed biasing voltage. When circuit elements are configured separately and not in stacked configurations, their biasing may be accomplished separately. In stacked configurations, however, biasing is often accomplished jointly in order to achieve optimal use of space and power.

Joint biasing schemes present a number of challenges. Process, supply and temperature variations for one circuit element may negatively affect the biasing of another circuit element. Moreover, the performance of circuits may be highly sensitive to variations in biasing. The performance of an LNA, for example, depends strongly on its transconductance (gm), which in turn depends strongly on its biasing. Methods and apparatuses consistent with the present invention provide a biasing scheme that overcomes these challenges and others.

### SUMMARY OF THE INVENTION

In one aspect of the present invention, a circuit is provided for compensating for a difference in the biasing currents of a first and second circuit element in a stacked circuit configuration. The circuit comprises (a) a first biasing source for biasing the first circuit element; (b) a second biasing source for biasing the second circuit element; and (c) a current-difference source for generating a difference current that is substantially equal to the difference in the biasing currents of the first and second circuit element.

In another aspect of the present invention, a method is provided for compensating for a difference in the biasing currents of a first and second circuit element in a stacked circuit configuration. The method comprises the steps of (a) biasing the first circuit element with a first biasing current; (b) biasing the second circuit element with a second biasing current; (c) generating a difference current substantially equal to the difference in the biasing currents of the first and second circuit element; and (d) supplying the difference current to the first circuit element to compensate for the difference in biasing currents.

In yet another aspect of the present invention, a communications apparatus is provided. The communications apparatus includes a transceiver with a first and second circuit element in a stacked circuit configuration. The transceiver comprises (a) means for biasing the first circuit element with a first biasing current; (b) means for biasing the second circuit element with a second biasing current; (c) means for generating a difference current substantially equal to the difference between the first and second biasing current; and (d) means for supplying the difference current to the first circuit element to compensate for the difference in biasing currents.

### BRIEF DESCRIPTION OF THE DRAWINGS

FIG. 1 illustrates a prior art LNA suitable for use with the present invention.

FIG. 2 illustrates a biasing scheme that is consistent with the present invention.

FIG. 3A illustrates a first embodiment of a stacked LNA/mixer configuration that is consistent with the present invention.

FIG. 3B illustrates a second embodiment of a stacked LNA/mixer configuration that is consistent with the present invention.

FIG. 3C illustrates a third embodiment of a stacked LNA/mixer that is consistent with the present invention.

FIG. 4 illustrates a prior art constant gm current source that is suitable for use with the present invention.

FIG. 5 illustrates a prior art constant IR current source that is suitable for use with the present invention.

FIG. 6 illustrates a prior art current-difference circuit that is suitable for use with the present invention.

FIG. 7 is a flowchart that illustrates steps associated with an exemplary method that is consistent with the present invention.

### DETAILED DESCRIPTION

Reference will now be made in detail to embodiments of the disclosed invention, one or more examples of which are illustrated in the accompanying drawings. Each example is provided by way of explanation of the present technology, not limitation of the present technology. In fact, it will be apparent to those skilled in the art that modifications and variations can be made in the present technology without departing from the spirit and scope thereof. For instance, features illustrated or described as part of one embodiment may be used on another embodiment to yield a still further embodiment. Thus, it is intended that the present subject matter covers such modifications and variations as come within the scope of the appended claims and their equivalents.

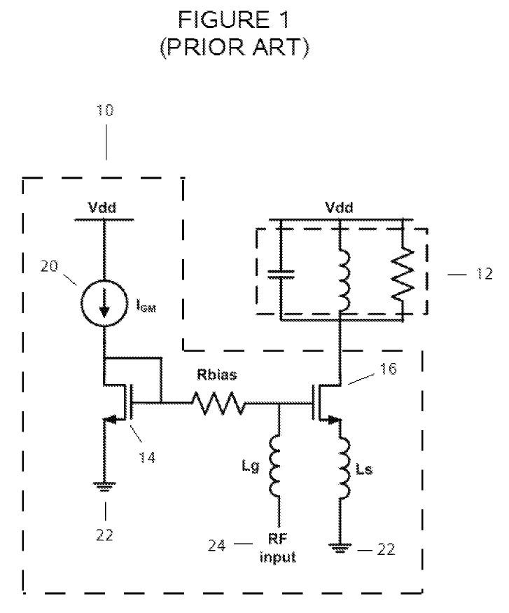

FIG. 1 illustrates a prior art LNA and biasing circuitry 10 that are suitable for use with the present invention. The LNA and biasing circuitry 10 include an LNA device 16 that is connected to a load 12. The load 12 may comprise, for example, some combination of capacitive, inductive and resistive components. The LNA and biasing circuitry 10 include a constant gₘ (transconductance) current source 20, which provides a constant current (I_{GM}) to a bias device 14. The bias device 14 may be, for example, an NMOS transistor with its drain and gate connected and its source connected to ground 22. The bias device 14 converts the I_{GM} current to a voltage for biasing the LNA device 16. Although an NMOS transistor is illustrated, the bias device 14 and the LNA device 16 may also be achieved using a bipolar transistor or other transistors. A bias resistor (Rbias) is connected between the bias device 14 and the LNA device 16 to provide high impedance between the two devices and to isolate the RF input 24 from the ground 22. The LNA topology shown in FIG. 1 is referred to as a common source inductively degenerated topology and includes two inductors, a gate inductor (Lg) and a source inductor (Ls). It should be noted that a number of additional LNA topologies are suitable for use with the present invention.

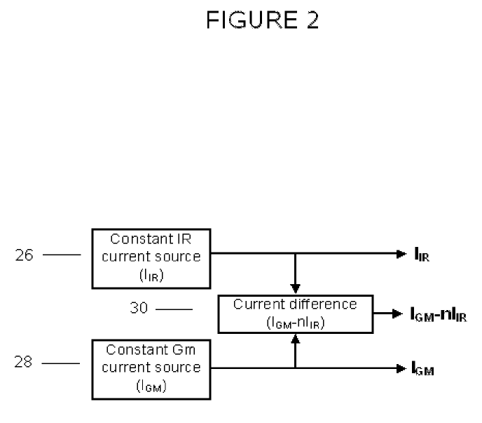

FIG. 2 is a block diagram that illustrates a biasing scheme that is consistent with the present invention. The biasing scheme includes three blocks: a constant IR current source 26, a constant gm current source 28 and a current-difference circuit 30. The current-difference circuit 30 is connected to the constant IR current source 26 and the constant gm current source 28 as illustrated. The current-difference circuit 30 generates a difference current that is substantially equal to the difference between the currents (I_{GM}−nI_{IR}). The difference current produced by the current-different circuit 30 includes a variable factor n that enables compensation in different circuit topologies.

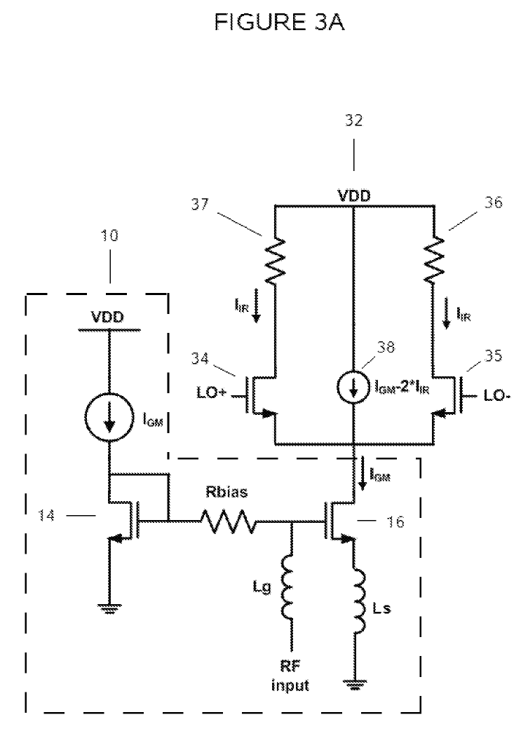

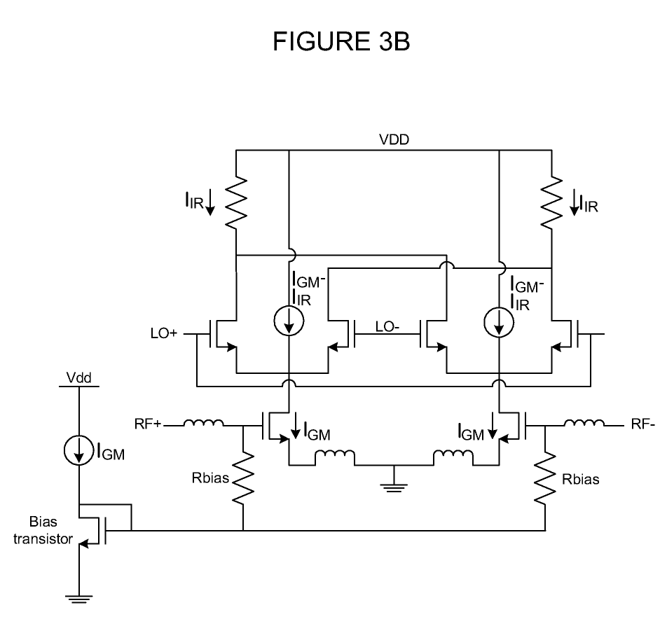

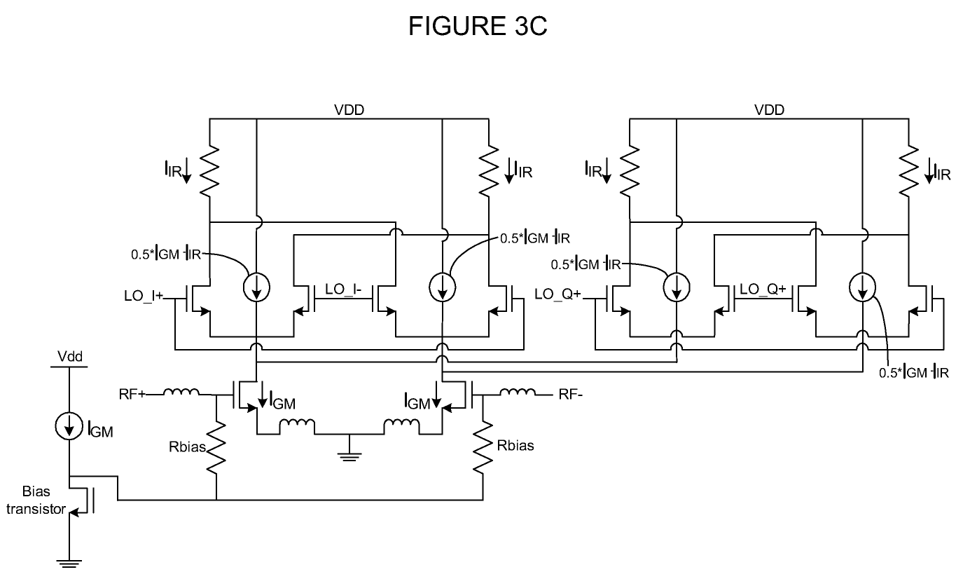

FIG. 3A illustrates a first embodiment of a stacked LNA/mixer configuration that is consistent with the present invention. The configuration includes an LNA and biasing circuitry 10 and a mixer 32. The LNA and biasing circuitry 10 may comprise, for example, the LNA and biasing circuitry 10 illustrated in FIG. 1. The mixer 32 may comprise, for example, a pair of mixer devices 34/35 and a pair of mixer loads 36/37. The mixer devices 34/35 are switched by local oscillators signals LO+ and LO−, respectively. As the mixer devices 34/35 are switched, current is diverted cyclically to each of the mixer loads 36/37 to perform up or down conversion in a communications system.

The performance of the LNA 10 depends strongly on its transconductance. Thus, a constant gₘ current I_{GM} is typically used to achieve the desired performance over process, temperature and supply variations. To keep the same voltage drop across the mixer load over process, temperature and supply variations, the constant IR biasing current I_{IR} is also needed for the mixer loads 36/37. The biasing currents I_{GM} and I_{IR}, however, may vary in a different manner over temperature, voltage and process variations. In order to compensate for such variations, a current-difference source 38 is connected between the LNA 10 and the mixer 32 as illustrated in FIG. 3A. The current-difference source 38 generates a difference current that is substantially equal to the difference between the I_{IR} current and the I_{GM} current (I_{GM}−2I_{IR}). This ensures that both the LNA device 16 and the mixer load 36/37 receive the constant biasing currents that they require.

FIG. 3B illustrates a differential double balanced stacked LNA/mixer configuration that is consistent with the present invention. This stacked LNA/mixer configuration is substantially similar to the one illustrated in FIG. 3A, except that the LNA in FIG. 3B has a differential configuration and its output feeds into a double balanced mixer. Again, the mixer devices are switched by local oscillators signals LO+ and LO−. Each LNA device is biased with a constant gₘ current I_{GM} and each mixer load has a constant IR current I_{IR} flowing through it. The current-difference source generates a difference current that is equal to the difference between the I_{IR} current and the I_{GM} current (I_{GM}−I_{IR}). This ensures that both the LNA device and the mixer load receive the constant biasing currents that they require.

FIG. 3C illustrates a differential double balanced I/Q stacked LNA/mixer that is consistent with the present invention. This stacked LNA/mixer configuration is substantially similar to the one illustrated in FIG. 3B, except that it includes both an I-mixer and a Q-mixer. The I-mixer is driven by the LO_I+ and LO_I− signals, whereas the Q-mixer is driven by the LO_Q+ and LO_Q− signals, resulting in both I and Q output signals. The current difference (0.5*I_{GM}−I_{IR}) is applied to the source node of the mixer devices, resulting in an I_{GM} current flowing in each LNA device and an I_{IR} current flowing in each mixer load. This ensures that both the LNA device and the mixer load receive the constant biasing currents that they require.

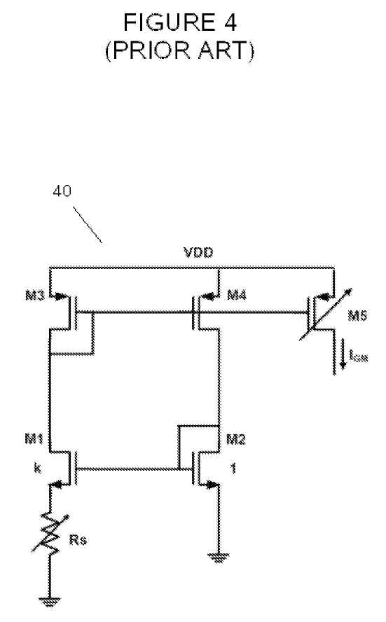

FIG. 4 illustrates a prior art constant gₘ current source 40 that is suitable for use with the present invention. The current source 40 generates a constant current (I_{GM}) for biasing an LNA. The current source 40 includes a plurality of transistors (M1 thru M5) and a variable resistor (R_{S}). The transistors and variable resistor are connected as illustrated in the figure. Transistors M3 and M4 function as a current mirror that force the current through the associated branches to remain equal. A current mirror is a circuit that is designed to copy a current through one active device by controlling the current in another active device. For improved matching between the current mirrors, the current mirrors may be implemented with cascode transistors. Transistors M1, M2 and resistor R_{S} generate the constant I_{GM} current. Transistor M1 has a device size that is a constant k times larger than the remaining transistors. Thus, the current I_{GM} may be expressed as

$${I}_{GM} = \frac{2}{{μ}_{n} {{C}_{ox} ( W / L )}_{n}} \frac{1}{{R}_{S}^{2}} {( 1 - \frac{1}{\sqrt{k}} )}^{2}$$

where μₙ, Cₒₓ and (W/L)ₙ are the parameters of the transistor M1, R_{S} is the size of the source resistor M1 and k is the device-size ratio of M1 relative to transistor M2. When the transistors of an LNA are matched to the M1 transistor and biased with the current I_{GM}, the transconductance (gₘ) of the LNA is given by

$${g}_{m} = \frac{2}{{R}_{s}} ( 1 - \frac{1}{\sqrt{k}} ) .$$

Thus, the transconductance of the LNA does not depend on transistor parameters. The only parameter that is affected by variations in process, temperature and supply is R_{S}. In order to make the current I_{GM} independent of variations in process, temperature and supply voltage, a tunable resistor R_{S} may be utilized. This enables such variations to be compensated for dynamically.

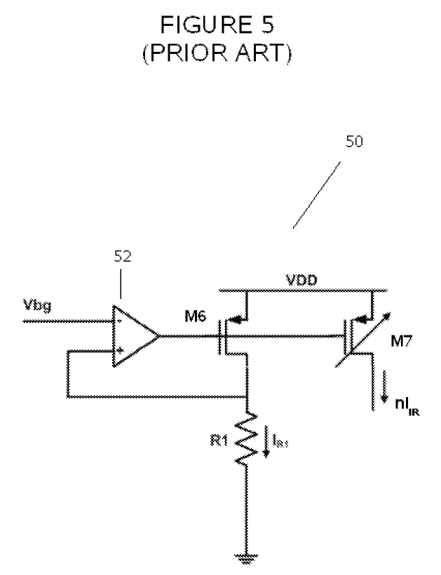

FIG. 5 illustrates a prior art constant IR current source 50 that is suitable for use with the present invention. The current source 50 includes an amplifier 52, transistors M6 and M7 and resistor R1. The components are connected as illustrated in the figure. The negative input of the amplifier 52 is supplied with a bandgap voltage Vbg, which is unaffected by process, supply and temperature variations. With sufficient amplifier gain, the voltage at the positive input of the amplifier 52 is also Vbg. Thus, the current flowing through the resistor R1 is determined as

$${I}_{R 1} = \frac{{V}_{bg}}{{R}_{1}} .$$

Since the bandgap voltage Vbg is independent of variations in process, temperature and supply voltage, the only variation to I_{R1} are caused by R1. I_{R1} is passed through a second resistor R2, and the voltage drop across the resistor is determined as

$${V}_{R 2} = {V}_{bg} ( \frac{{R}_{2}}{{R}_{1}} )$$

Thus, the voltage drop across resistor R2 is a function of the bandgap voltage and the ratio of two resistors, which is essentially independent of variations in process, temperature and supply voltage. To improve the matching between resistors R1 and R2, they may be selected to be multiples of a unit transistor. To obtain different values of I_{IR}, the constant IR current can be selected from an array of binary weighted current mirrors.

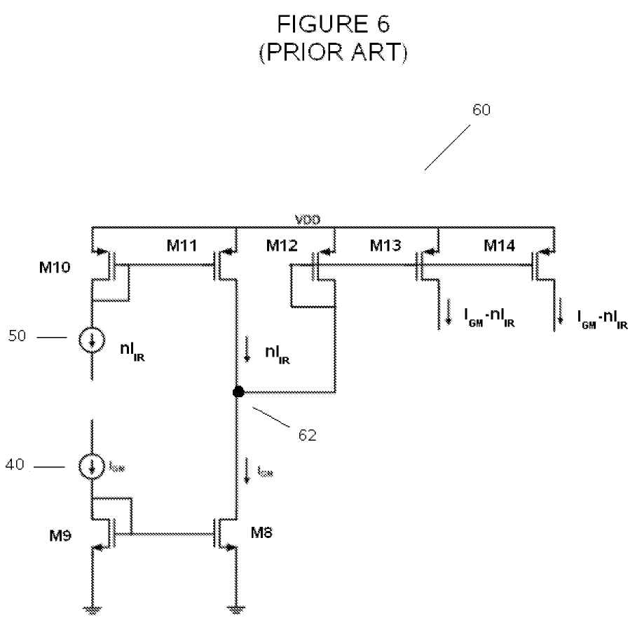

FIG. 6 illustrates a prior art current-difference source 60 that is suitable for use with the present invention. The current-difference source 60 includes seven transistors (M8 through M14). Transistor M8 is biased with the constant current I_{GM} by current source 40, and transistor M11 is biased with the constant current nI_{IR} by the current source 50. Transistors M8, M11 and M12 are connected to form a current-summing node 62 as illustrated in the figure. A current of nI_{IR} flows into the current-summing node and a current of I_{GM} flows out of the current-summing node. This forces the current through transistor M12 to be equal to the difference between the two currents. The current difference is mirrored in two current branches by the current mirrors associated with transistors M13 and M14, which supply the current difference I_{GM}-nI_{IR} to the stacked LNA/mixer. For improved matching between the current mirrors, the current mirrors may be implemented with cascode transistors.

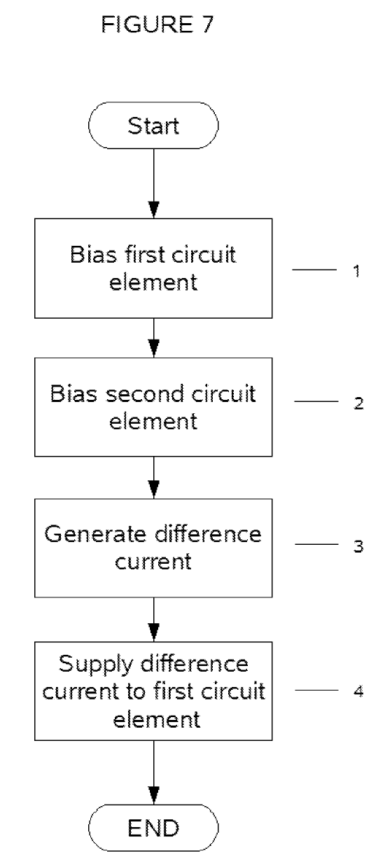

FIG. 7 is a flowchart that illustrates steps associated with a general method that is consistent with the present invention. The method involves compensating for a difference in the biasing currents of a first and second circuit element in a stacked circuit configuration. Step 1 involves biasing the first circuit element with a first constant current. Step 2 involves biasing the second circuit element with a second constant current. Step 3 involves generating a difference current that is substantially equal to the difference in the biasing currents of the first and second circuit element. Step 4 involves supplying the difference current to the first circuit element to compensate for the difference in biasing currents.

Although the invention has been discussed primarily with respect to specific embodiments thereof, other variations are possible. For example, although the invention has been described in one context, it is equally applicable to both up- and down-conversion. The invention may also be implemented using transistor technology other than MOS technology, such as bipolar technology. In addition, the steps associated with methods described herein may be performed by hardware or software, as desired. Steps may also be added to, taken from or modified from the steps in this specification without deviating from the scope of the invention. Any flowcharts presented are only intended to indicate one possible sequence of basic operations to achieve a function, and many variations are possible. Those of skill in the art will also appreciate that methods and apparatuses consistent with the present invention are suitable for use in a wide range of stacked or multi-chip circuit configurations, including various combinations of amplifiers, mixers and filters and are also suitable for use in a wide range of applications, including communications systems such as mobile telephony, WiFi and Bluetooth.

While the specification has been described in detail with respect to specific embodiments of the invention, it will be appreciated that those skilled in the art, upon attaining an understanding of the foregoing, may readily conceive of alterations to, variations of, and equivalents to these embodiments. These and other modifications and variations to the present invention may be practiced by those of ordinary skill in the art, without departing from the spirit and scope of the present invention, which is more particularly set forth in the appended claims. Furthermore, those of ordinary skill in the art will appreciate that the foregoing description is by way of example only, and is not intended to limit the invention.

What is claimed is:

1. A circuit for compensating for a difference in biasing currents of a first and second circuit element in a stacked circuit configuration, comprising:
a first biasing source for biasing said first circuit element;
a second biasing source for biasing said second circuit element; and
a current-difference source for generating a difference current that is substantially equal to said difference in said biasing currents of said first and second circuit element;
wherein said current-difference source supplies said difference current to compensate for said difference in said biasing currents of said first and second circuit element.

2. The circuit of claim 1 wherein said first circuit element is a low noise amplifier and said second circuit element is a mixer.

3. The circuit of claim 2 wherein said first constant biasing source is a constant gₘ current source.

4. The circuit of claim 3 wherein said second constant biasing course is a constant IR current source.

5. The circuit of claim 1 wherein said current-difference source includes a current-summing note for generating said difference current and a plurality of current mirrors for supplying said difference current to said first circuit element.

6. The circuit of claim 3 wherein said constant gₘ current source includes a variable resistor for dynamically compensating for process, temperature and supply variations.

7. A method of compensating for a difference in biasing currents of a first and second circuit element in a stacked circuit configuration, comprising the steps of:
biasing said first circuit element with a first biasing current;
biasing said second circuit element with a second biasing current;
generating a difference current substantially equal to said difference in said biasing currents of said first and second circuit element; and
supplying said difference current to said first circuit element to compensate for said difference in biasing currents.

8. The method of claim 7 wherein said first circuit element is a low noise amplifier and said second circuit element is a mixer.

9. The method of claim 8 wherein said biasing of first circuit element comprises supplying a constant gₘ current.

10. The method of claim 9 wherein said biasing of said second circuit element comprises supplying a constant IR current.

11. The method of claim 7 wherein said step of generating a difference current comprises supplying said first constant current and said second constant current to a current-summing node to generate said difference current.

12. The method of claim 11 wherein said step of supplying said difference current to said first circuit element comprises mirroring said difference current with a current mirror.

13. The method of claim 9 wherein said step of supplying a constant gₘ current comprises tuning a variable resistor to dynamically compensate for process, temperature and supply variations.

14. A communications apparatus having a transceiver with a first and second circuit element in a stacked circuit configuration, comprising:
means for biasing said first circuit element with a first biasing current;
means for biasing said second circuit element with a second biasing current;
means for generating a difference current substantially equal to the difference between said first and second biasing current; and
means for supplying said difference current to said first circuit element to compensate for said difference in biasing currents.

15. The communications apparatus of claim 14 wherein said first circuit element is a low noise amplifier and said second circuit element is a mixer.

16. The communications apparatus of claim 15 wherein said first constant biasing source is a constant gₘ current source.

17. The communications apparatus of claim 16 wherein said second constant biasing course is a constant IR current source.

18. The communications apparatus of claim 14 wherein said current-difference source includes a current-summing note for generating said difference current and a plurality of current mirrors for supplying said difference current to said first circuit element.

19. The communications apparatus of clam 16 wherein said constant gₘ current source includes a variable resistor for dynamically compensating for process, temperature and supply variations.
